(19) United States
(12) Patent Application Publication
(10) Pub. No.: US 2019/0019908 A1
(43) Pub. Date: Jan. 17, 2019

(54) Solar Panel Interconnection System

(71) Applicant: Celestica International Inc., Toronto (CA)

(72) Inventors: David John LEKX, Toronto (CA); Seyed Mohsen MAHMOUDYSEPEHR, Toronto (CA)

(21) Appl. No.: 16/133,165

(22) Filed: Sep. 17, 2018

Related U.S. Application Data
(63) Continuation of application No. PCT/CA2017/050338, filed on Mar. 15, 2017.
(60) Provisional application No. 62/309,071, filed on Mar. 16, 2016.

(51) Int. Cl. H01L 31/049; H01L 31/02; H01L 31/05; H02S 40/34

(52) U.S. Cl. CPC H01L 31/049; H02S 40/34; H01L 31/0516; H01L 31/02021

(57) ABSTRACT

A backsheet for a solar panel assembly is provided. The backsheet includes one or more embedded conductive elements that are positioned to make parallel connections between solar cells connected in series in a solar panel when applied to the solar panel. The backsheet can be used for solar cells that are assembled in one or more substrings of shingled cells connected in series to each other, or wherein the solar cells are assembled in a back-contact configuration, the backsheet further comprising connective elements for series connections between cells.

### CROSS-REFERENCE TO RELATED APPLICATION(S)

This application is a continuation of PCT Application No. PCT/CA2017/050338 filed on Mar. 15, 2017, which claims priority to U.S. Provisional Patent Application No. 62/309,071 filed on Mar. 16, 2016, both incorporated herein by reference.

### TECHNICAL FIELD

The following relates to systems for interconnecting solar panels, particularly in providing in-backsheet solar cell bussing.

### DESCRIPTION OF THE RELATED ART

The manufacturing of photovoltaic (PV) solar panels can utilize several different mechanisms for interconnecting solar cells and extracting power from the cells in the panel. Most commonly, cells are connected in series with “string ribbons” or “tabs” connecting the front of a cell to the back of an adjacent cell. Other structures include what are known as “back-contact” cells, wherein both positive and negative connections of the cells are on the back side of the cell, which avoids shading the front side of the panel. Both of these structures generally have all of the cells in the panel in series with a cumulative voltage at the output and a common current in all the cells.

A third structure for interconnecting cells involves the “shingling” of cells in series so that the top edge of a cell is underneath, and in direct contact with, the bottom edge of an adjacent cell, and connected using solder, conductive paste, or some other conductive element. The use of shingling has been in practice for decades, as illustrated in U.S. Pat. No. 3,769,091.

All of the above-noted interconnection mechanisms are most commonly implemented using cells connected in series. However, a less common approach to interconnecting cells is to connect them in parallel or a parallel/series combination. This has been found to provide the most redundancy and highest resilience in terms of energy harvesting. Such parallel connection implementations are illustrated, for example, in U.S. Pat. No. 4,315,096 and PCT publication WO 2013/066998.

### SUMMARY

In one aspect, there is provided a backsheet for a solar panel assembly, the backsheet comprising one or more embedded conductive elements that are positioned to make parallel connections between solar cells in a solar panel when applied to the solar panel in the solar panel assembly.

The backsheet can be configured in one implementation to be used with solar cells that are assembled in one or more substrings of shingled cells. The backsheet can also be configured in another implementation to be used with solar cells that are assembled in a back-contact configuration. The backsheet's embedded conductive circuit patterns can be electrically connected to the solar panel using a conductive material, such as a conductive thermal adhesive applied prior to a lamination process and cured through it, or applied and cured prior to a lamination process.

In another aspect, there is provided a solar panel assembly comprising the back sheet described above. The solar panel assembly can include a sheet of glass positioned behind the backsheet in at least one implementation.

### BRIEF DESCRIPTION OF THE DRAWINGS

Embodiments will now be described by way of example only with reference to the appended drawings wherein:

FIG. 1 is a perspective view illustrating assembly of a substring of solar cells by shingling;

FIG. 2 is a perspective view illustrating an assembled substring with a conductive tab at one end;

FIG. 3 is a plan view of an embedded backsheet for providing parallel or quasi-parallel connectivity to solar cells;

FIG. 4 is a plan view of the embedded backsheet of FIG. 3 applied to a set of substrings assembled as shown in FIGS. 1 and 2;

FIG. 5 is a plan view of an alternative embedded backsheet using smaller point connections, shown applied to a set of substrings assembled as shown in FIGS. 1 and 2;

FIG. 6 is an exploded perspective view of a solar panel laminate assembly with the embedded backsheet shown in FIG. 5;

FIG. 7 is a perspective view from above, illustrating assembly of a substring of solar cells by shingling without the use of a separate busbar tab;

FIG. 8 is a perspective view from below, illustrating assembly of a substring of solar cells by shingling without the use of a separate busbar tab;

FIG. 9 is a perspective view from the backside, illustrating an assembled substring with connection points for parallel electrical connections;

FIG. 10 is a plan view of a backsheet attached to a panel with embedded contact points within the cells;

FIG. 11 is a perspective view from below, illustrating assembly of a substring of solar cells by shingling as an alternative to the parallel output bus pattern shown in FIG. 8;

FIG. 12 is a perspective view from the backside, illustrating an assembled substring with connection points for parallel electrical connections per the alternative shown in FIG. 11;

FIG. 13 is a plan view of a backsheet attached to a panel with embedded contact points within the cells per the alternative shown in FIGS. 11 and 12;

FIG. 14 is a plan view of a back-contact cell bussing structure for serial connections, embedded in a backsheet; and

FIG. 15 is a plan view of a back-contact cell bussing structure for quasi-parallel connections, embedded in a backsheet.

### DETAILED DESCRIPTION

In one aspect, it has been recognized that achieving a parallel/series connection implementation with shingled tiles is typically more complex when using traditionally available bussing methods. These traditional methods involve using busbar strips at intervals along the shingled tiles, which would connect the shingled strings in parallel, and take those outputs to other common busbar elements as well as other shingled strings. The aforementioned arrangement also necessitates extensive use of insulator strips between the busbars and the cells that are not at the common current and voltage levels. This would also necessitate soldering or otherwise making joints via thermally conductive paste or other mechanisms including but not limited to welding and soldering, set above the cells and spread throughout the laminate, ahead of second encapsulant placement and substrate placement, be it a backsheet of various plastic materials or a second sheet of glass.

It has been found that this problem can be alleviated by putting these conductive busbar elements into a plastic backsheet solution, similar to backsheet connections made in back-connect cells. However, the solution proposed herein provides an interconnection system that eliminates an entirely different set of materials, by enabling parallel or quasi-parallel connections, with minimal to no additional manufacturing or assembly burden.

Whereas back-contact cell conductive elements in a backsheet are configured to make connections between adjacent cells for positive/negative series connections, the system described herein includes elements that connect cells and substrings in parallel and form alternate paths for electrons to take throughout the panel to complete the circuit. The principles discussed herein can be applied in both shingled and back-contact implementations.

The parallel backsheet connection system described herein is particularly useful and efficient for manufacturing this type of PV panel because it eliminates a great deal of manual operations in bussing and layup. Moreover, the entire process from the layup and placement of the strings, through placement/dispensation of the conductive element making the bond to the backsheet, and through the placement of the parallel-conductive backsheet; could be primarily or entirely automated with very limited human intervention aside from monitoring the equipment.

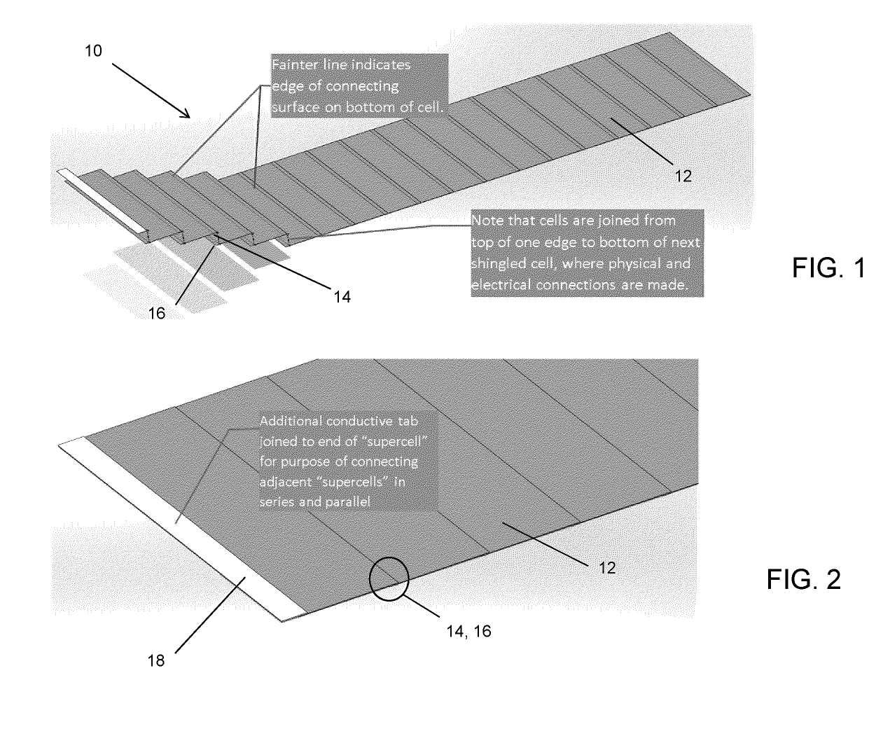

Turning now to the figures, FIG. 1 illustrates assembly of a substring 10 or “supercell” of individual solar cells 12 by shingling. As shown in FIG. 1, a first busbar element 14 on the underside and at one end of the cell 12 being added is connected to a second busbar element 16 on the topside and at the other end of the cell 12 to which it is being added to achieve serial connections between adjacent cells 12. FIG. 2 illustrates an enlarged view of an assembled portion of the substring 10. A conductive element 18 may be included at one end of the substring 10 as shown in FIG. 2. The conductive element 18 is used to connect adjacent substrings 10 to each other, in series and/or in parallel.

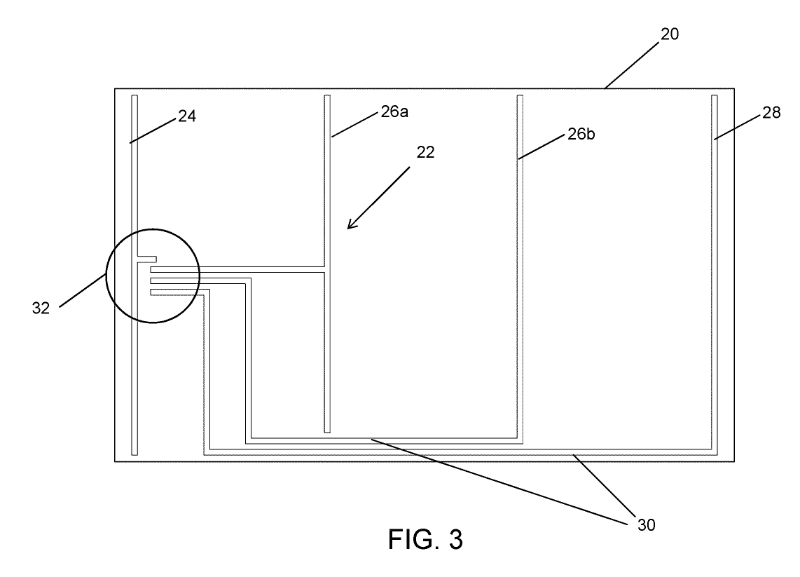

A number of substrings 10 are typically included in a single solar panel assembly and are series connected by way of the conductive elements 18. However, as noted above, these structures have not been incorporated into a parallel or quasi-parallel configuration into a backsheet. FIG. 3 illustrates a schematic plan view of a backsheet 20 having an embedded bussing structure 22. The embedded bussing structure 22 in this example provides a quasi-parallel arrangement, although it can be appreciated that fully parallel configurations are also possible. It is noted that by quasi-parallel, it is meant that a number of cells 12 are connected in series, and then in parallel. The embedded bussing structure 22 includes a parallel input busbar 24, a first parallel midpoint busbar element 26a, a second parallel midpoint busbar element 26b, and an output busbar element 28 running across the adjacent substrings 12 to connect the serially connected substrings 10 to each other when attached thereto. These transverse elements 24, 26, 28 are carried towards an electrical input/output area 32 via routing busbar elements 30, some of which are routed about the edge of the backsheet 20. It can be appreciated that the patterning shown in FIG. 3 is illustrative only and can be modified to suit the architecture of the underlying/overlying solar cells 12. It can also be appreciated that the elements 24, 26, 28, 30 may be stamped or cut out of a single piece, or assembled in some manner.

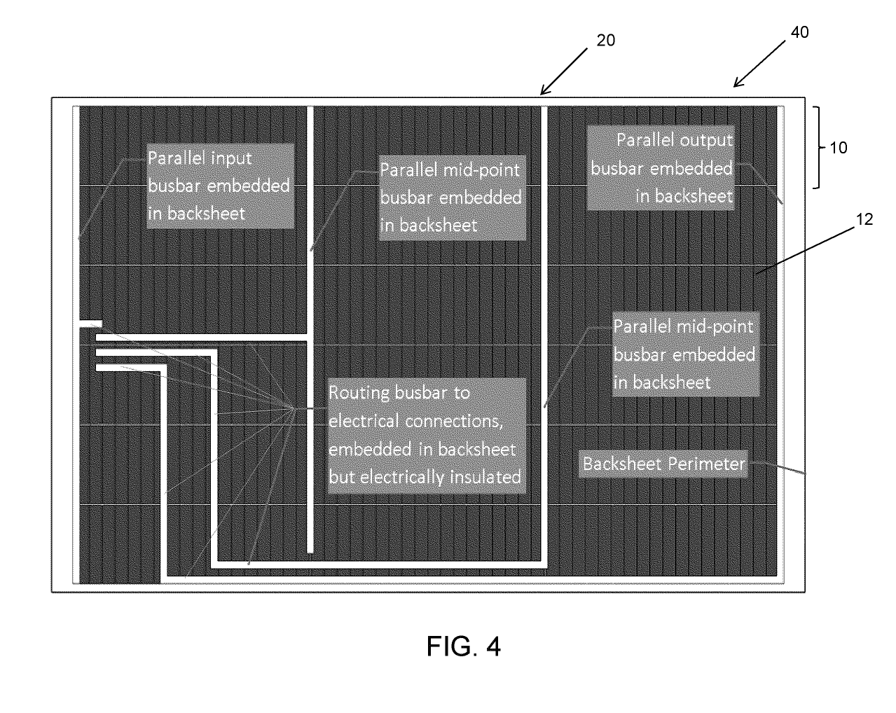

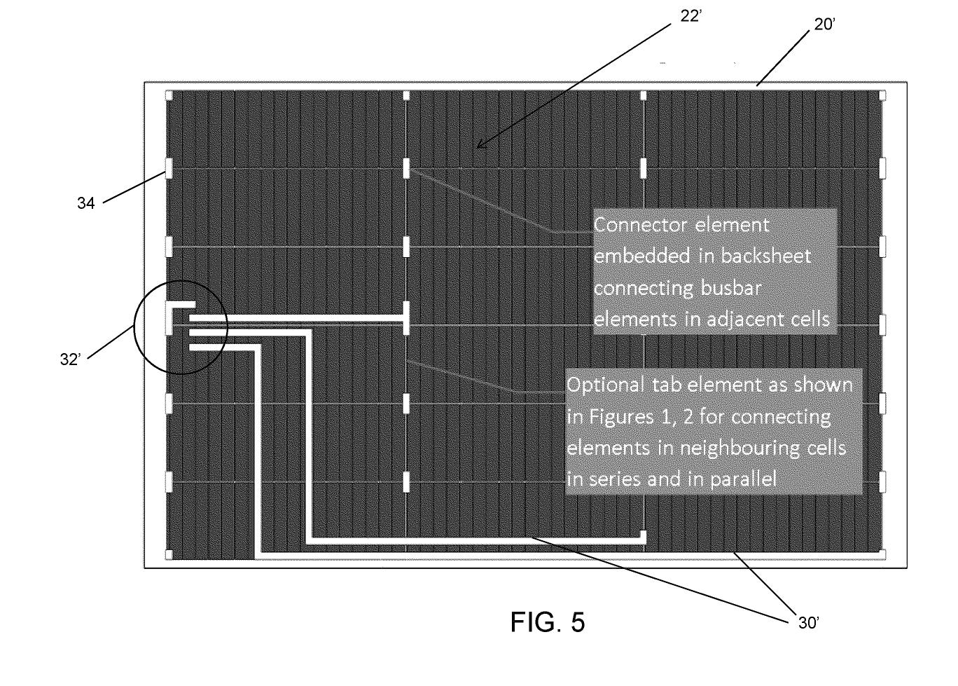

FIG. 4 illustrates the backsheet 20 in FIG. 3 applied to a solar panel assembly 40 composed of a number of adjacent substrings 10 of solar cells 12. It can be appreciated that the balance of the backsheet 20 (i.e. other than the conductive elements 24, 26, 28, 30) is shown transparently for illustrative purposes.

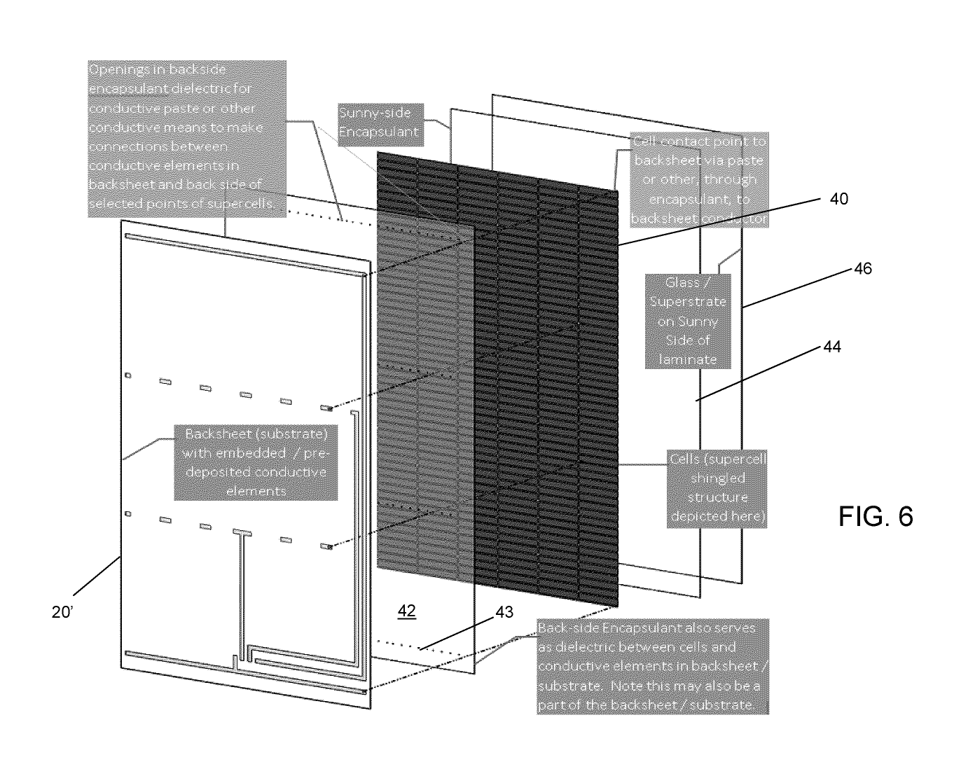

FIG. 5 illustrates an alternative embodiment for a quasi-parallel embedded busbar structure 22′ in which the parallel bussing is achieved using a number of smaller point connections 34 to busbar tabs 14, 16 or connection points of the cells 12. The parallel paths therefore run through a combination of the backsheet 20 and the cells 12 via the point connections 34. A modified input/output area 32′ and routing busbar elements 30′ are shown, which extend between one of the point connections 34 along a parallel path (positioned similar to the parallel busbar elements 24, 26, 28 in FIG. 3) and the modified input/output area 32′. It may be noted that the embodiment shown in FIG. 5 can include the tabs 18 at the end of each substring 10 as shown in FIGS. 1 and 2. However, an additional connection point could instead be provided on the backside of the shingles specifically for the purpose of making similar interconnections (both series and parallel) with the elimination of the copper busbar if possible as shown in FIGS. 6-8 described below.

It can be appreciated that various mechanisms can be used to attach the conductive elements (24, 26, 28, 34) of the backsheet 20 to the solar assembly 40, for example using a conductive thermal adhesive during a laminating process, soldering, adhesive tape, etc. Also, an encapsulant can also be included as part of the backsheet 20, between the embedded bussing structure 22 and a balance of the typical backsheet composition, and the solar cells 12, or can be applied separately. The encapsulant, whether applied as part of the backsheet or separately, may also be used as a dielectric in some embodiments, and have openings therein to allow electrical connections to be made in specific regions.

FIG. 6 illustrates an example of a panel laminate in an exploded view. The embedded backsheet 20′ shown in FIG. 5 is illustrated by way of example with a back-side encapsulant 42 interposed between the backsheet 20′ and the solar panel assembly 40. It may be noted that the back-side encapsulant 42 may be a part of the backsheet 20′ or separate as shown, and thus it is shown as being separate in FIG. 6 for ease of illustration. The back-side encapsulant 42 includes a series of openings 43 to allow for conductive paste or other conductive materials to make connections between the conductive elements in the backsheet 20′ and the back-side of the selected points of contact of the substrings 10. It can be appreciated from FIG. 6 that the back-side encapsulant 42 also serves as a dielectric to prevent short circuits within the panel assembly 40, and that the openings 43 would provide the only way for the current to travel through the back-side encapsulant 42 to the backsheet conductive elements. It can also be appreciated that the shape and locations of the openings 43 in the back-side encapsulant 42 may vary considerably within the principles discussed herein, particularly to accommodate different positioning and shapes/contours of conductive elements.

FIG. 6 also illustrates a sunny-side encapsulant 44 interposed between the solar panel assembly 40 and a glass superstrate 46 applied to the sunny side of the laminate.

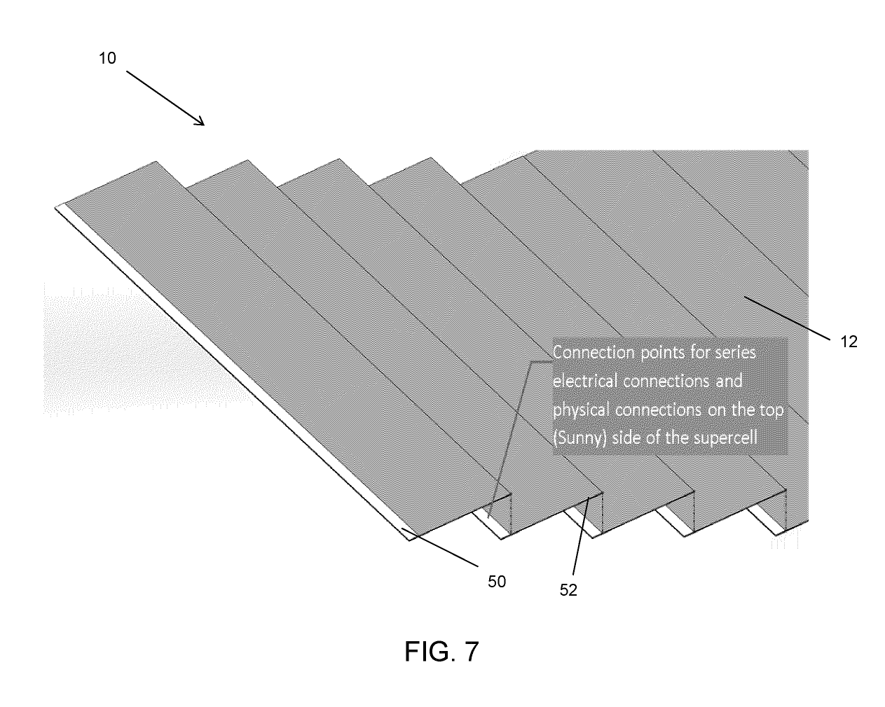

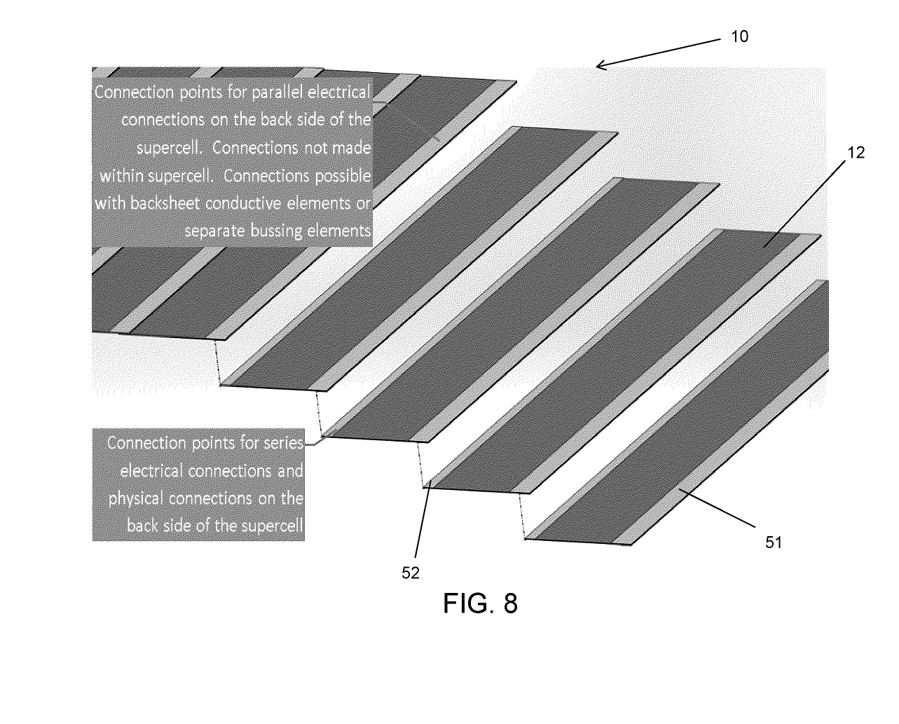

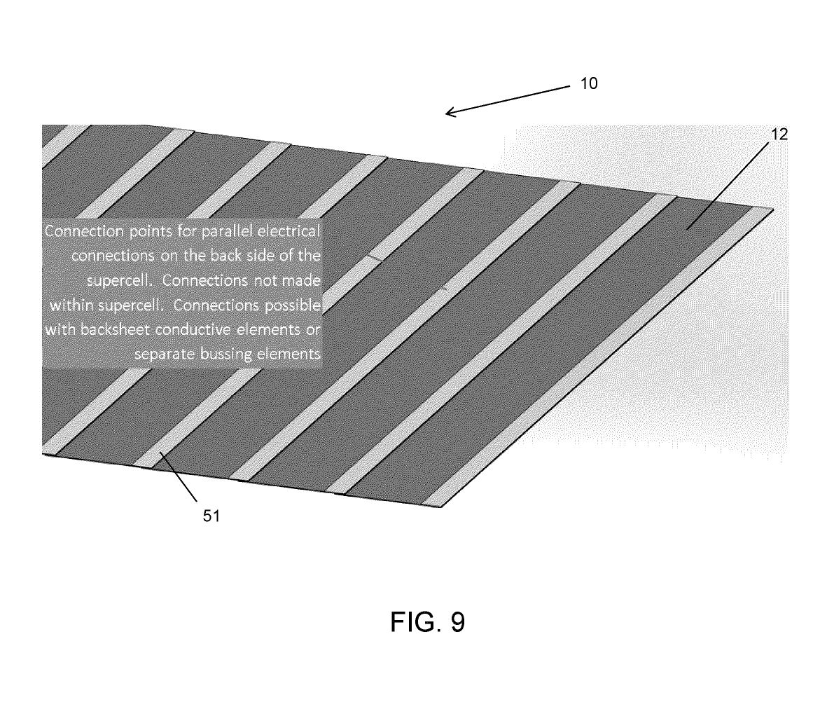

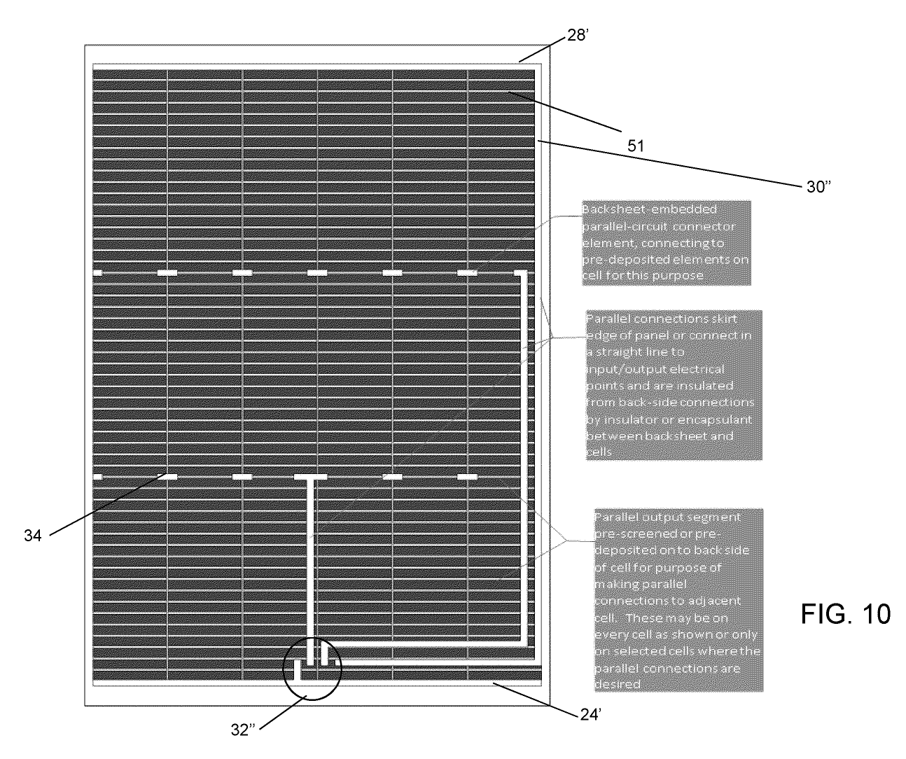

FIG. 7 illustrates a shingled substring 10 being assembled, which includes an additional conductive element on the backside (not seen in FIG. 6) which allows for the elimination of the tab 18 shown in FIGS. 1 and 2. In FIG. 7, a first conductive element 50 is shown which connects to a second conductive element 52 on the adjacent cell 12 in the substring 10. As best seen in FIG. 8, the second conductive element 52 provides a connection point for series electrical connection and physical connections on the backside of the substring 10, via the first conductive element 50 of the adjacent cell 12. Also shown in FIG. 8 is an additional parallel conductive element 51 for parallel electrical connections to the backside of the substring 10. In this example, connections are not made within the supercell, connections are possible with backsheet conductive elements or separate bussing elements connected to the parallel conductive elements 51. FIG. 9 illustrates the substring 10 being assembled in FIGS. 7 and 8, in an assembled configuration, from the backside of the cells 12. The connection points 51 can be seen in this view and it can be appreciated that with this arrangement, one can eliminate the need for the separate busbar tabs 18 depicted in FIGS. 1, 2, and 5.

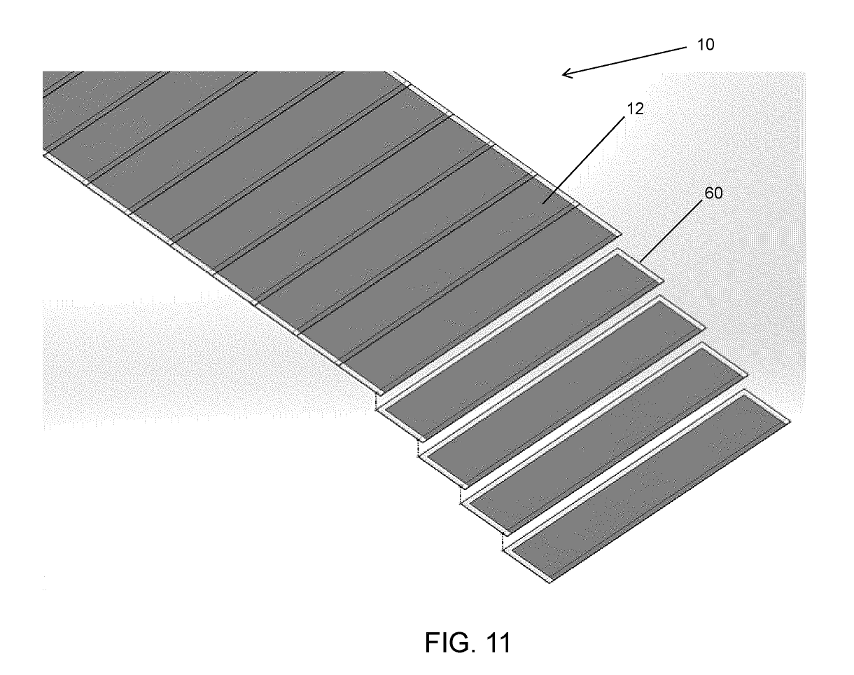

FIG. 10 provides a plan view of an assembled panel in which the parallel conductive elements 51 can be seen. These parallel output segments 51 can be pre-screened or pre-deposited on to the backside of the cells 12 for the purpose of making parallel connections to adjacent cells 12. It can be appreciated that such parallel conductive elements 51 can be on every cell 12 as shown in this example, or on select cells where the parallel connections are desired. It can also be appreciated that while parallel busses are depicted in FIG. 10 using point connections 34 as shown in FIG. 5, continuous embedded conductive segments 24, 26, 28 as shown in FIG. 3, can also be used with the substring 10 shown in FIGS. 7-9, and may be considered preferable in some applications.

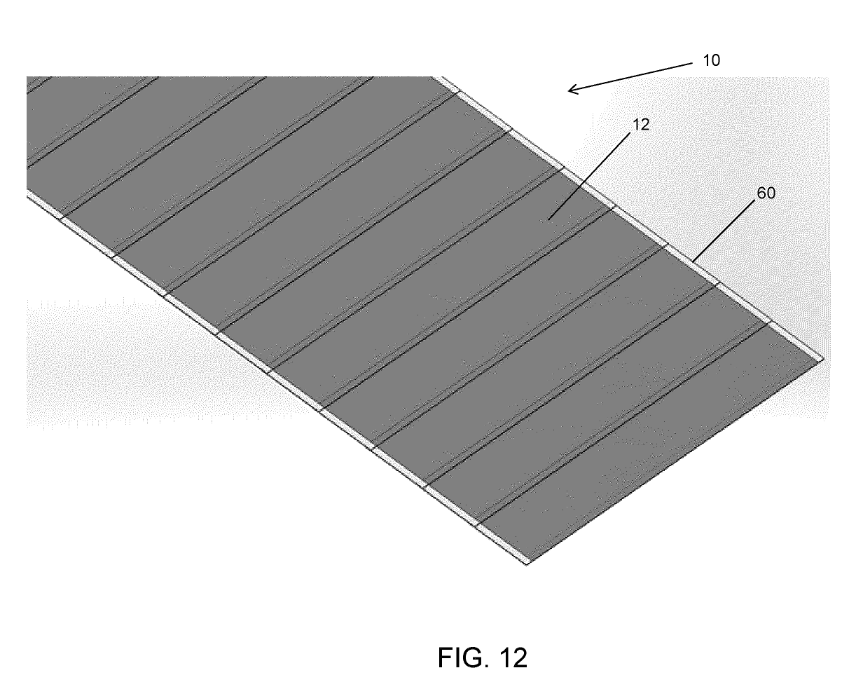

FIG. 11 provides an alternative back-side parallel output bus pattern to that shown in FIGS. 8 and 9. In this alternative, parallel outputs are provided using conductive strips 60 along the short ends of the cells 12 rather than continuous strips along the long sides as shown in FIGS. 8 and 9, depending on the existing bus at the opposite side (which is hidden by the shingling as seen in FIG. 12). In this configuration, the parallel connection output is achieved by bridging the small outer tabs 60 via the conductive elements 22, 22′ in the backsheet 20, 20′.

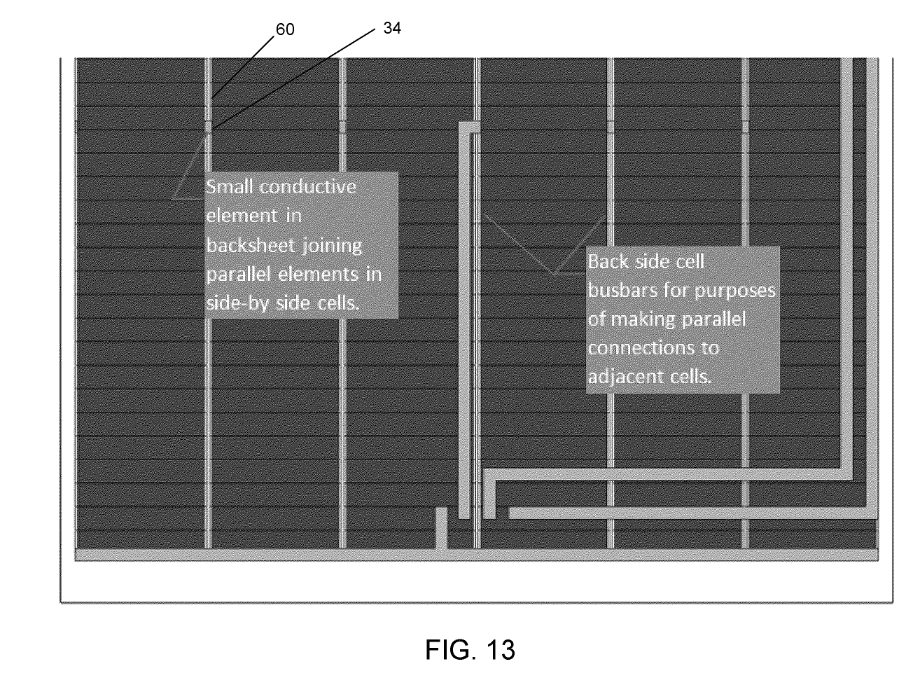

FIG. 13 provides a view of a laminate showing the alternative back-side bus pattern of FIGS. 11 and 12 used to connect to the embedded backsheet conductive elements 22′ of the embodiment shown in FIG. 5. As seen in FIG. 13, the back-side busbars 60 provide a means for making parallel connections to adjacent cells 12 and the small conductive elements 34 in the backsheet 20′ join parallel elements in such adjacent cells 12. It may be noted that the parallel elements 60 in the cells 12 and the cells themselves are prevented from shorting to the other electrical elements in the backsheet 20′ by virtue of the dielectric encapsulant 42 (e.g., see FIG. 6) between the cells 12 and the backsheet conductive elements 22′. The dielectric encapsulant 42 may be an outer layer of the backsheet product as shipped to the panel manufacturer, or applied separately by the manufacturer.

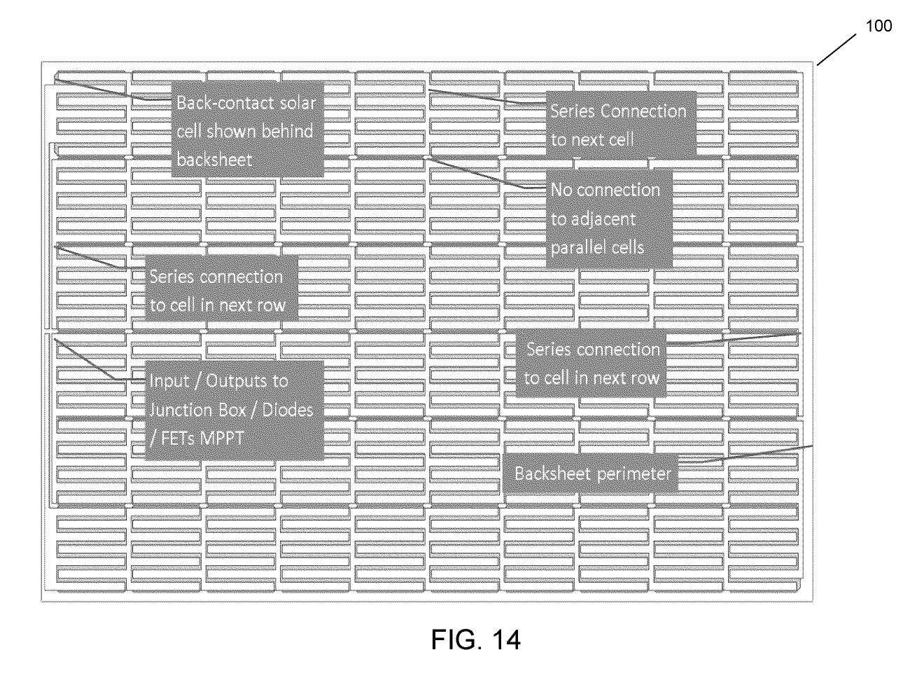

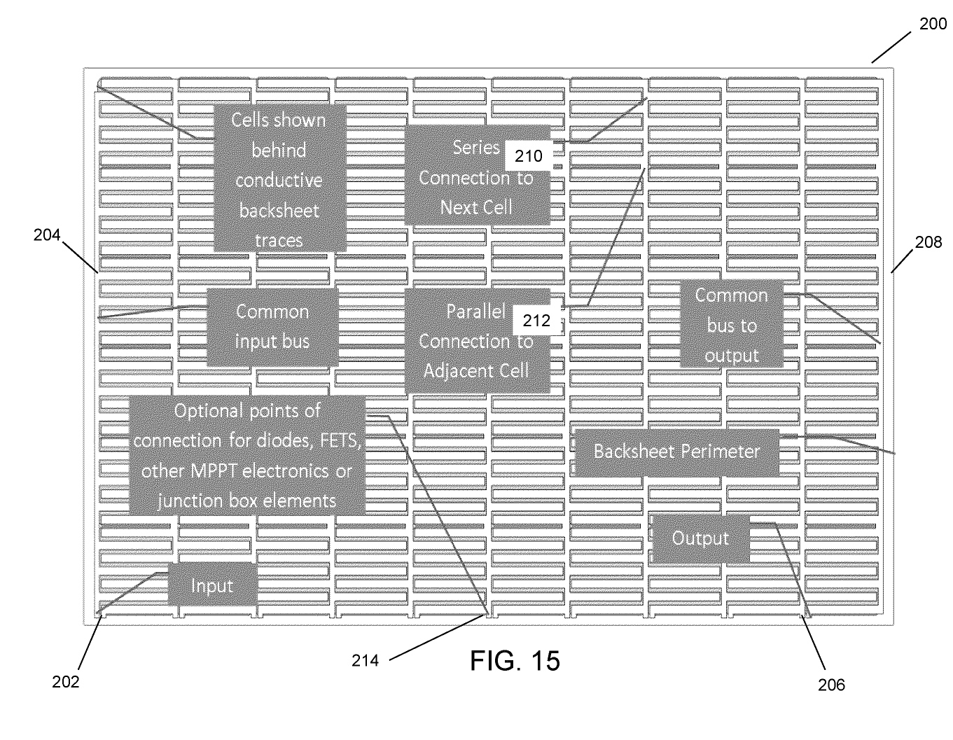

While the examples shown in FIGS. 1 to 13 illustrate an embedded backsheet 20, 20′ for a shingled cell arrangement, it can be appreciated that the backsheet 20, 20′ can also be adapted for use with a back-contact cells, wherein both positive and negative connections of the cells are on the back side of the cell. FIG. 14 illustrates a typical series back-contact cell bussing structure embedded in a backsheet 100. In this configuration, all cell interconnects are done through the backsheet 100 and without the backsheet 100, no cell connections are provided due to the use of a back-contact arrangement. That is, when compared to a shingled approach, the back-contact arrangement does not have any connections without the backsheet 20 whereas the shingled cells 12 are already connected in series. Therefore, the backsheet 20 shown in FIG. 4 provides the redundancy of the parallel connections as well as the input and output, while relying on the shingled connections to provide the series connections. The arrangement shown in FIG. 14 provides the same series connectivity of the shingled substrings 12, but for back-contact cells. In order to provide the additional redundancy of the parallel connections for a back-contact arrangement, the backsheet 200 shown in FIG. 15 is required.

As can be seen in FIG. 15, the fingering of the conductive elements provides series and parallel connections between cells. The patterning in FIG. 15 includes an input 202 and common input bus 204 that connect into the fingering between cells 12, which are shown behind the backsheet traces. Also shown are an output 206 and a common output bus 208 at the opposite end of the backsheet 200 to the input bus 204. A series connection to a next cell 12 is identified by numeral 210, and a parallel connection to an adjacent cell 12 is identified by numeral 212. Numeral 214 identifies an additional point of connection for diodes, FETs, other MPPT electronics or junction box elements. It may be noted that the points of connection 214 are across the parallel elements in this implementation rather than a portion of a series connection as is the case in traditional panels. It can be appreciated that the structure shown in FIG. 15 is applicable to full-size cells 12 and smaller cells 12 that are cut into various sizes and arranged into supercells, like the shingled approach described above.

Accordingly, there is provided a backsheet 20, 20′ with embedded copper or aluminum or other conductive material into it for the purpose of making parallel connections between crystalline silicon cells 12 or substrings 10. In one aspect, they can be connected by shingling the cells 12 together, with connections to the backsheet 20 (e.g. as shown in FIG. 4) accomplished through a conductive element, such as a thermal adhesive which can form a bond through the lamination process so that no extra manufacturing step is required. In another aspect, a backsheet 200 can be adapted for use with back-contact cells instead of shingled cells where both series and parallel connections are embedded in the backsheet 200 as shown in FIG. 15.

The backsheet 20 can also include an integrated encapsulant between the conductive backsheet and the cells 12 as shown in FIG. 6. Moreover, a second sheet of glass can be provided behind the backsheet 20 as an additional element.

The backsheet 20 as herein described can be used with various types of solar PV cells 12, for example crystalline silicon, crystalline bifacial cells, hetero-junction cells, or bifacial hetero-junction cells, and thin film cell structures.

A solder connection can be used instead of conductive paste for joining the cells to the embedded conductive elements connecting strings within the backsheet. Similarly, any other suitable conductive connection, such as conductive tape, etc., or any suitable means for joining the cells to the embedded conductive elements connecting strings within the backsheet 20, can be used.

As illustrated in FIG. 5, a backsheet construction is also provided which has small point connections 34 included in the backsheet 20, rather than long strips, which could be used to a similar effect using the fingers and bussing within the cells 12 and leveraging novel finger patterns in the back sides of cells (as shown in FIG. 9), to achieve similar effects.

A backsheet is also provided which integrates bussing mechanisms for traditional non-back-contact series-architected panels to connect substrings and diodes; and/or integrates bussing mechanisms and electronics for power optimisation such as bypass diodes or FETs, power optimiser chips, etc.

A transparent material can also be provided in the backsheet 20 (except for the conductive elements) to make the backsheet 20 suitable for bifacial cells.

For simplicity and clarity of illustration, where considered appropriate, reference numerals may be repeated among the figures to indicate corresponding or analogous elements. In addition, numerous specific details are set forth in order to provide a thorough understanding of the examples described herein. However, it will be understood by those of ordinary skill in the art that the examples described herein may be practiced without these specific details. In other instances, well-known methods, procedures and components have not been described in detail so as not to obscure the examples described herein. Also, the description is not to be considered as limiting the scope of the examples described herein.

It will be appreciated that the examples and corresponding diagrams used herein are for illustrative purposes only. Different configurations and terminology can be used without departing from the principles expressed herein. For instance, components and modules can be added, deleted, modified, or arranged with differing connections without departing from these principles.

The steps or operations in the flow charts and diagrams described herein are just for example. There may be many variations to these steps or operations without departing from the principles discussed above. For instance, the steps may be performed in a differing order, or steps may be added, deleted, or modified.

Although the above principles have been described with reference to certain specific examples, various modifications thereof will be apparent to those skilled in the art as outlined in the appended claims.

1. A backsheet for a solar panel assembly, the backsheet comprising one or more embedded conductive elements that are positioned to make parallel connections between solar cells connected in series in a solar panel when the backsheet is applied to the solar panel.

2. The backsheet of claim 1, wherein the solar cells are assembled in one or more substrings of shingled cells connected in series to each other.

3. The backsheet of claim 1, wherein the solar cells are assembled in a back-contact configuration, the backsheet further comprising connective elements for series connections between cells.

4. The backsheet of claim 1, wherein the embedded conductive circuit patterns are electrically connected to the solar panel using a conductive material.

5. The backsheet of claim 4, wherein the conductive material is provided using a conductive thermal adhesive applied prior to a lamination process and cured through it, or applied and cured prior to the lamination process.

6. The backsheet of claim 4, wherein the conductive material is provided by soldering or welding.

7. The backsheet of claim 1, further comprising an integrated encapsulant interposed between the conductive elements and the solar cells.

8. The backsheet of claim 1, wherein the solar cells are of any of the following types: crystalline silicon, crystalline bifacial cells, hetero-junction cells, bifacial hetero-junction cells, and thin film cell structures.

9. The backsheet of claim 1, wherein the embedded conductive elements comprise either point connections between particular adjacent substrings or transverse strips connecting the adjacent substrings.

10. The backsheet of claim 1, wherein embedded conductive elements comprise points of connection for any one or more of diodes, FETs, MPPT electronics, or junction box elements.

11. The backsheet of claim 1, wherein embedded conductive elements comprise bussing mechanisms and electronics for power optimization.

12. The backsheet of claim 11, wherein the electronics for power optimization comprise any one or more of bypass diodes, FETs, or power optimiser chips.

13. The backsheet of claim 1, comprising transparent material around the embedded conductive elements for use with bifacial cells.

14. The backsheet of claim 1, comprising conductive material deposited onto a surface of the backsheet.

15. A solar panel assembly comprising a backsheet, the backsheet comprising one or more embedded conductive elements that are positioned to make parallel connections between solar cells connected in series in a solar panel when the backsheet is applied to the solar panel.

16. The solar panel assembly of claim 15, further comprising a sheet of glass positioned behind the backsheet.

17. The solar panel assembly of claim 15, wherein the solar cells are assembled in one or more substrings of shingled cells connected in series to each other.

18. The solar panel assembly of claim 15, wherein the solar cells are assembled in a back-contact configuration, the backsheet further comprising connective elements for series connections between cells.

19. The solar panel assembly of claim 15, wherein the embedded conductive circuit patterns are electrically connected to the solar panel using a conductive material.
